(19) United States
(12) Patent Application Publication
(10) Pub. No.: US 2008/0121940 A1
(43) Pub. Date: May 29, 2008

(54) Semiconductor Device and Fabricating Method Thereof

(76) Inventor: JIN HA PARK, Echeon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/930,542

(22) Filed: Oct. 31, 2007

(30) Foreign Application Priority Data
Nov. 27, 2006 (KR) 10-2006-0117457

(51) Int. Cl. H01L 27/115; H01L 21/8247

(52) U.S. Cl. 257/203; 438/128; 257/E27.103; 257/E21.68

(57) ABSTRACT

A flash memory device with a system in package (SIP) structure and a fabricating method thereof are provided. In the semiconductor device of an embodiment, a flash memory device is formed by forming cell transistors and high voltage transistors on different wafers, and connecting each of vertically stacked chips in a via pattern. According to an embodiment, a device isolating layer and a device can be fabricated to be met with the features of the cell transistor which is not affected by the high voltage transistor, a gap fill margin of the device isolating device in forming the cell transistor is large, and the degree of integration is increased to improve yield. Also, the high voltage transistors in a driving circuit unit can be designed and fabricated without suffering from the effect of the cell transistor.

### CROSS-REFERENCE TO RELATED APPLICATION

The present application claims the benefit under 35 U.S.C. §119 of Korean Patent Application No. 10-2006-117457, filed Nov. 27, 2006, which is hereby incorporated by reference in its entirety.

### BACKGROUND

As generally known, as a semiconductor device becomes miniaturized and highly integrated, the semiconductor package should also be small and light to maximally implement the features of such a semiconductor device.

A fine circuit technology used for fabricating the semiconductor device is difficult to properly apply to each product due to the extension of the development period, a vast facility investment, and rapid increase in processing cost.

Meanwhile, a flash memory device, which has been a spotlighted storage medium, is a nonvolatile memory device that maintains information stored in a memory cell thereof despite being not applied with power, and can rapidly and electrically erase the information.

Transistors used for the flash memory device are largely classified into three types: cell transistor, high voltage driving transistor, and low voltage driving transistor.

FIG. 1 is a cross-sectional view showing a part of a cell area and a high voltage driving area in a flash memory device of the related art.

As shown in FIG. 1, the flash memory device is constituted by a cell area for storing a flash data, a high voltage transistor for storing data in the cell, and a logic, or low voltage, transistor driving the high voltage transistor.

For the high voltage transistor, the operating voltage is 5 V, the voltage used in programming the data using several circuits is 9 V, and the voltage used in erasing the data uses −8 V using Fowler-Nordheim (FN) tunneling. For the logic, or low voltage, transistor, the operating voltage is 3 V.

However, in order to write and erase the data in the cell of the flash memory device, breakdown voltage is an important factor in the high voltage transistor supplying high voltage, wherein the depth of a device isolating layer has a great effect on the breakdown voltage.

In other words, if the depth ‘a’ of the device isolating depth is less than or the same as the junction depth, the high voltage transistor causes a punch through ‘A’ below the device isolating layer, degrading the device property.

### BRIEF SUMMARY

Embodiments of the present invention provide a flash memory device with a system in package (SIP) structure and a fabricating method thereof.

An embodiment provides a semiconductor device with a system in package structure and fabricating method thereof which forms cell transistors and high voltage transistors on different wafers, vertically stacks chips from the respective wafers, and connects each of the vertically stacked chips using a via pattern.

There is provided a semiconductor device according to one embodiment, comprising: a first chip having cell transistors formed in a predetermined area on a first semiconductor substrate formed with a first device isolating layer; a second chip stacked on the first chip and having high voltage transistors for applying driving voltage to the cell transistors and formed in a predetermined area on a second semiconductor substrate formed with a second device isolating layer having a second depth deeper than the first depth; and an insulating film formed between one surface of the first chip and one surface of the second chip.

There is provided a fabricating method of a semiconductor device according to an embodiment, comprising: forming cell transistors on a first wafer; preparing a first chip by cutting the first wafer; forming high voltage transistors for driving the cell transistors on a second wafer; preparing a second chip by cutting the second wafer; interposing an insulating film between one surface of the first chip and one surface of the second chip; and forming a via pattern electrically connecting the cell transistors and the high voltage transistors.

### BRIEF DESCRIPTION OF THE DRAWINGS

FIG. 1 is a cross-sectional view showing a part of a cell area and a high voltage driving area in a flash memory device in the related art.

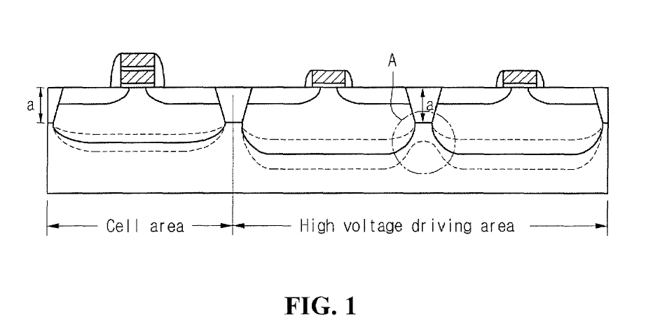

FIG. 2 is a cross-sectional view showing a part of a first wafer according to an embodiment of the present invention.

FIG. 3 is a cross-sectional view showing a part of a second wafer according to an embodiment of the present invention.

FIG. 4 is a cross-sectional view showing a system in package according to an embodiment of the present invention.

### DETAILED DESCRIPTION

The semiconductor device according to an embodiment of the present invention is fabricated as one package by making a cell area and high voltage transistors for driving a cell area on separate wafers and then vertically stacking them.

The method fabricating a semiconductor device as one package by vertically stacking the same kinds or various kinds of the semiconductor devices and mutually connecting between the circuits of the wafer or the chips stacked in a via pattern may be referred to as a system in package SiP.

Since the system in package vertically stacks the chips unlike an existing single chip package, even when the same kind of chips are stacked, the storage density can be increased. A package of composite functions can be fabricated by stacking chips having an information storing function and a logic arithmetic function so that the final product can be small, light and multi-functional.

Further, since the system in package is one that combines and can package existing developed semiconductor chips, the development period is fast and value added in the final product is increased by using the existing facility as it is, the demand of many customers can easily be met, and a new market is created due to various products.

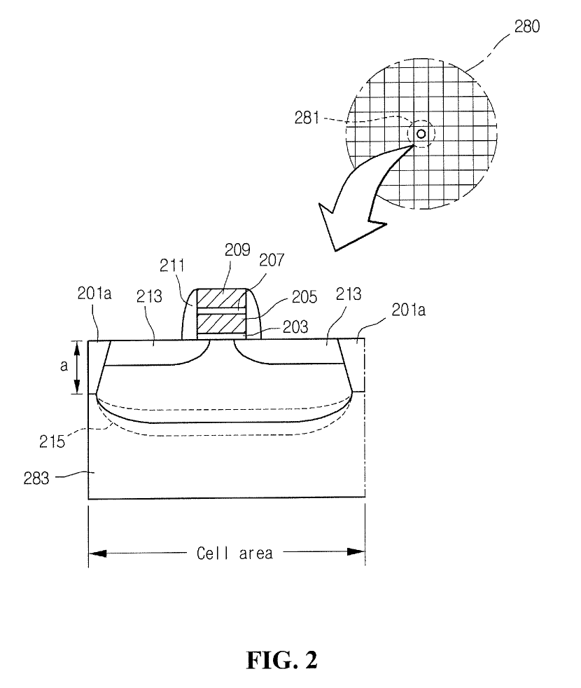

FIG. 2 is a cross-sectional view showing a part of a first wafer according to an embodiment.

As shown in FIG. 2, cell area transistors can be formed on the first wafer 280. The first wafer 280 can be formed with only cell area type transistors. The first wafer 280 can be divided into a plurality of chips 281. The first semiconductor substrate 283 of the first wafer 280 can be formed with a first device isolating layer 201a having a proper depth ‘a’ for the cell transistors.

The formation of a first device isolating layer 201a having the proper depth ‘a’ in the cell transistors means the formation of the first device isolating layer 201a to have the depth capable of inhibiting a punch through caused by connection of depletion layers 215 at the side and below the device isolating layer isolating neighboring transistors when driving the cell transistors.

The cell transistors are formed in an active area of the first semiconductor substrate 283. The active area can be defined by means of the first device isolating layer 201a formed on the first semiconductor substrate 283.

The active area on the first semiconductor substrate 283 can be implanted with impurity to form a well, and the flash memory gate electrode can be formed on the first semiconductor substrate 283. The well boundary indicates the depletion layer 215.

The flash memory gate electrode can include a first gate oxide film 203, a floating gate 205, a second gate oxide film 207, and a control gate 209 on the first semiconductor substrate 283.

In operation, electrons pass through the first gate oxide film 203 by means of a positive (+) voltage applied to the control gate 209 and are injected into the floating gate 205, thereby performing a program operation. And, electrons pass through the first gate oxide film 203 by means of negative (−) voltage applied to the control gate 209 and transfer into the first semiconductor substrate 100, thereby performing an erase operation.

A first spacer 211 can be formed on sidewalls of the flash memory gate electrode. The first spacer 211 can be formed of, for example, a tetra ethyl ortho silicate (TEOS) or a nitride film.

Impurity can be implanted into the first semiconductor substrate 283 at sides of the flash memory gate electrode to form a first source/drain area 213.

The cell transistor of the flash memory device having such a structure can store and erase flash data. However, the flash memory device should include a high voltage transistor used to store the data in the cell transistor.

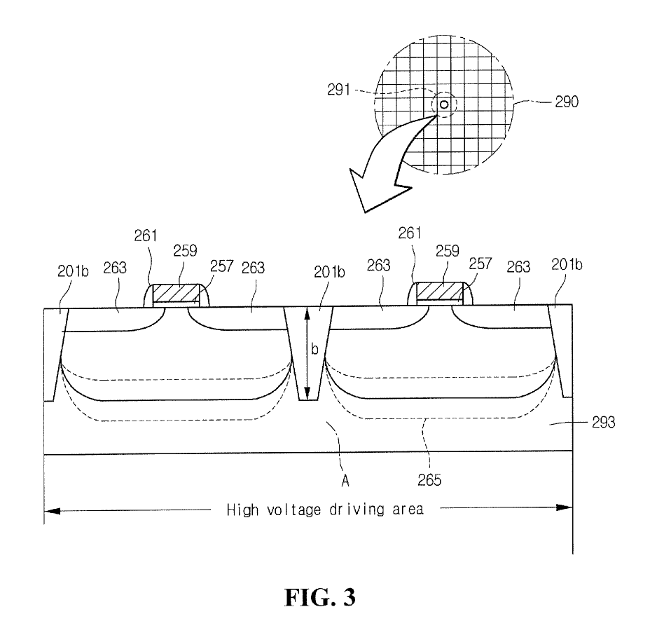

FIG. 3 is a cross-sectional view showing a part of a second wafer according to an embodiment.

The second wafer 290 can be formed with the high voltage transistors for driving the cell transistor described with respect to FIG. 2. In one embodiment, the second wafer 290 can be formed with only high voltage transistors. The second wafer 290 can be divided into a plurality of chips 291.

Referring to FIG. 3, the high voltage transistors can be formed in an active area of a second semiconductor substrate 293. The second semiconductor substrate 293 of the second wafer 290 is formed with a second device isolating layer 201b having a proper depth ‘b’ for the high voltage transistor.

The formation of a second device isolating layer 201b having the proper depth ‘b’ for the high voltage transistors means the formation of the second device isolating layer 201b to have the depth capable of inhibiting punch through caused by the connection of depletion layers 265 at the side and below the device isolating layer isolating neighboring transistors when driving the high voltage transistors.

The proper depths ‘a’ and ‘b’ of the device isolating layers 201a and 201b for the cell transistors and the high voltage transistors are different. In particular, the device isolating layer should be more deeply formed for the high voltage transistor compared to the device isolating layer for the cell transistors. At this time, the cell pitch is small so that when the depth of the device isolating layer is deep without condition, gap fill can be difficult and voids can be generated. As a result of the unconditional depth, device defects may occur because of the voids. Accordingly, according to embodiments of the present invention, the system in package is fabricated by forming the device isolating layers having a proper depth for the cell transistors and cell transistors on the first wafer, forming the device isolating layers having a proper depth for the high voltage transistors and high voltage transistors on the second wafer, and then vertically stacking the first wafer and the second wafer and mutually connecting them through the via pattern.

The device isolating layer fabricated for the cell transistor can be made such that the cell transistor does not suffer from the effects of fabricating the high voltage transistor. Accordingly, the gap fill margin of the device isolating layer can be increased when forming the cell transistor, and the degree of integration can be increased to improve yield.

Also, the high voltage transistors can be designed and fabricated in the driving circuit unit without suffering from the effect of fabricating the cell transistors.

In addition, by fabricating the cell transistors and the high voltage transistors separately and then combining them in a system in a package, it is possible to reduce the process time by about 30%.

Preferably, the depth ‘b’ of the second device isolating layer 201b is deeper than the depth ‘a’ of the first device isolating layer 201a in the first wafer 280.

The second device isolating layer 201b can define an active area of the second semiconductor substrate 293. the high voltage transistors can be formed in the active area of the second semiconductor substrate 293.

Impurity can be implanted into active area of the second semiconductor substrate 293 to form a well, and the high voltage gate electrode can be formed on the second semiconductor substrate 293. The well boundary indicates the depletion layer 265.

The high voltage gate electrode can include a poly gate 259 and a gate insulating film 257 formed between the poly gate 259 and the second semiconductor substrate 293.

A second spacer 261 can be formed on sidewalls of the high voltage gate electrode. The second spacer 261 can be formed of, for example, a tetra ethyl ortho silicate (TEOS) or a nitride film.

In addition, the second semiconductor substrate 293 can be implanted with impurity sides of the high voltage gate electrode to form a second source/drain area 263.

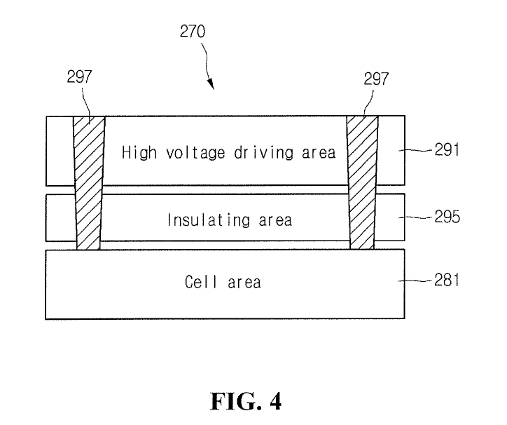

FIG. 4 is a cross-sectional view showing a system in package according to an embodiment.

Referring to FIG. 4, a flash memory device 370 in the system in package structure according to an embodiment includes a first chip 281 provided from the first wafer 280, a second chip 291 provided from the second wafer 290, and an insulating film 295 interposed between the first chip 281 and the second chip 291 for an insulation.

The insulating film 295 can be formed of, for example, a tetra ethyl ortho silicate (TEOS).

The first wafer 280 can have a structure as described with reference to FIG. 2, and the first chip 281 provided from the first wafer 280 is formed with the cell transistors.

The second wafer 290 can have a structure as described with reference to FIG. 3, and the second chip 291 provided from the second wafer 290 is formed with the high voltage transistors.

The first chip 281 and the insulating film 295 can be formed with a via hole and a via pattern 297 formed of metal buried in the via hole such that the first chip 281 and the second chip 291, which are vertically stacked, can electrically be connected.

Also, a low voltage driving transistor can be fabricated on a separate wafer and then stacked on the first chip 281 and the second chip 291 so that it can be included in the system in package.

In another embodiment, the low voltage driving transistor can be formed on the first wafer 280 with the cell transistors formed on the first wafer 280, or the low voltage driving transistor can be formed on the second wafer 290 with the high voltage transistors formed on the second wafer 290.

Embodiments of the present invention can be used to fabricate device isolating layers such that the cell transistors can be not affected by the fabricating process of the high voltage transistors. This allows a gap fill margin of the device isolating device in forming the cell transistor to be increased, and increases the degree of integration to improve yield.

Embodiments of the present invention can be used to design and fabricate the high voltage transistors in a driving circuit unit without suffering from the effects of the cell transistor.

In addition, by forming the cell transistors and the high voltage transistors separately and then combining them in the system in package, it can be possible to reduce the process time by about 30%.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

It should be understood that the examples and embodiments described herein are for illustrative purposes only and that various modifications or changes in light thereof will be suggested to persons skilled in the art and are to be included within the spirit and purview of this application.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a first chip having cell transistors in a predetermined area on a first semiconductor substrate formed with a first device isolating layer;
a second chip having high voltage transistors for applying driving voltage to the cell transistors in a predetermined area on a second semiconductor substrate formed with a second device isolating layer, wherein the second device isolating layer has a depth deeper than the depth of the first device isolating layer; and
an insulating film between one surface of the first chip and one surface of the second chip.

2. The semiconductor device according to claim 1, further comprising a via pattern electrically connecting the first chip and the second chip through the insulating film.

3. The semiconductor device according to claim 1, wherein the cell transistors comprise:
a flash memory gate electrode on the first semiconductor substrate;
a first spacer on sidewalls of the flash memory gate electrode; and
a source/drain area in the first semiconductor substrate at sides of the flash memory gate electrode.

4. The semiconductor device according to claim 1, wherein the high voltage transistors comprise:
a high voltage gate electrode on the second semiconductor substrate;
a second spacer on sidewalls of the high voltage gate electrode; and
a source/drain area in the second semiconductor substrate at sides of the high voltage gate electrode.

5. The semiconductor device according to claim 4, wherein the high voltage gate electrode comprises polysilicon.

6. The semiconductor device according to claim 1, wherein the insulating film comprises a tetra ethyl ortho silicate (TEOS).

7. A method of fabricating a semiconductor device, comprising:
forming cell transistors on a first wafer;
preparing a first chip by cutting the first wafer;
forming high voltage transistors for driving the cell transistors on a second wafer;
preparing a second chip by cutting the second wafer;
interposing an insulating film between one surface of the first chip and one surface of the second chip; and
forming a via pattern electrically connecting the cell transistors and the high voltage transistors.

8. The method according to claim 7, further comprising:
forming a first device isolating layer having a first depth on the first wafer.

9. The method according to claim 8, further comprising:
forming a second device isolating layer having a second depth deeper than the first depth.

10. The method according to claim 7, wherein forming the cell transistors on the first wafer comprises:
forming a flash memory gate electrode on the first wafer;
forming a first spacer on sidewalls of the flash memory gate electrode; and
forming a source/drain area by implanting impurity at sides of the flash memory gate electrode.

11. The method according to claim 7, wherein forming the high voltage transistors on the second wafer comprises:
forming a high voltage gate electrode on the second wafer;
forming a second spacer on sidewalls of the high voltage gate electrode; and
forming a source/drain area by implanting impurity at sides of the high voltage gate electrode.
